(19) United States
(12) Patent Application Publication
(10) Pub. No.: US 2023/0170282 A1
(43) Pub. Date: Jun. 1, 2023

(54) NON-COPLANAR OR BUMPED LEAD FRAME FOR ELECTRONIC ISOLATION DEVICE

(71) Applicant: TEXAS INSTRUMENTS INCORPORATED, Dallas, TX (US)

(72) Inventors: Yuntao Xu, Chengdu (CN); Min Hui Ma, Chengdu (CN); Tiange Xie, Chengdu (CN); Rongwei Zhang, Plano, TX (US)

(21) Appl. No.: 17/537,923

(22) Filed: Nov. 30, 2021

(51) Int. Cl. H01L 23/495; H01L 23/00; H01L 23/31; H01L 21/56

(52) U.S. Cl. CPC H01L 23/49513; H01L 24/32; H01L 24/73; H01L 23/3121; H01L 23/49541; H01L 24/83; H01L 21/56; H01L 2224/32245; H01L 2224/32013; H01L 2224/73265; H01L 2224/8385

(57) ABSTRACT

A semiconductor device includes a silicon die having a first side and a second side, an adhesive layer attached to the first side of the silicon die, and a lead frame. The lead frame comprises a die attach pad having a mounting surface. The mounting surface has a smaller area than an area of the adhesive layer. The silicon die is mounted on the lead frame at the mounting surface so that edges of the silicon die and the adhesive layer overhang the die attach pad without touching the die attach pad. The semiconductor device further includes one or more leads that are spaced apart from the edges of the silicon die and the adhesive layer.

### BACKGROUND

The lead frame in a semiconductor package is a structure that carries signals from a semiconductor die to external leads. The semiconductor die inside the package is typically mounted to the lead frame. Bond wires attach the semiconductor die to the leads. Lead frames are manufactured by removing material, such as by etching or stamping. The lead frame may also be modified by adding structures, such as bumps to support the semiconductor die. During manufacture of a semiconductor package, silicon debris may be induced during wafer dicing with a saw. The silicon debris may cause electronic grounding or a short when the semiconductor die is mounted on the lead frame.

### SUMMARY

An integrated circuit package includes a silicon die having a first side and a second side, an adhesive layer attached to the first side of the silicon die, and a lead frame. The lead frame includes a die attach pad having a mounting surface. The mounting surface has a smaller area than an area of the adhesive layer. The silicon die is mounted on the lead frame at the mounting surface so that edges of the silicon die and the adhesive layer overhang the die attach pad without touching the die attach pad. The semiconductor device further includes one or more leads that are spaced apart from the edges of the silicon die and the adhesive layer.

A semiconductor device includes a silicon die having a first side and a second side, an adhesive layer attached to the first side of the silicon die, and a lead frame. The lead frame includes a plurality of leads. The leads have a first end, a second end, and a central portion between the first end and the second end. A bump is formed on each of the first ends of the leads. The silicon die is mounted on the bumps so that edges of the silicon die and the adhesive layer overhang the central portion of the leads without touching the central portion of the leads and the second ends of the leads extend beyond the edges of the silicon die and the adhesive layer.

A method of making a semiconductor device includes providing a silicon wafer having a backside, coating the wafer backside with an adhesive layer, sawing the silicon wafer to create a semiconductor die, and providing a lead frame. The lead frame includes a die attach pad having a mounting surface. The mounting surface has a smaller area than an area of the adhesive layer. The lead frame further includes one or more leads. The method further includes mounting the silicon die on the lead frame at the mounting surface so that edges of the silicon die and the adhesive layer overhang the die attach pad without touching the die attach pad, and encapsulating the semiconductor die, the adhesive layer, and the lead frame with a mold compound so that the mold compound fills a space where the edges of the silicon die and the adhesive layer overhang the die attach pad.

### BRIEF DESCRIPTION OF THE DRAWINGS

Having thus described the invention in general terms, reference will now be made to the accompanying drawings, wherein:

FIG. 1 illustrates a semiconductor package including a semiconductor die that has been singulated from a semiconductor wafer using a saw dicing process that creates silicon debris.

FIG. 2 illustrates an example semiconductor package including a semiconductor die and silicon debris that is isolated from the lead frame by mounting the semiconductor die so that it overhangs a lead frame.

FIG. 3 is a top view of the example semiconductor package of FIG. 2 illustrating the spatial relationship between a semiconductor die, a die attach pad, and lead frame leads.

FIG. 4 illustrates an example semiconductor package having an etched lead frame configuration for isolating the semiconductor die and silicon debris from the lead frame.

FIG. 5 illustrates an example semiconductor package having a grooved lead frame configuration for isolating the semiconductor die and silicon debris from the lead frame.

FIG. 6 illustrates an example semiconductor package having a bumped lead frame configuration for isolating the semiconductor die and silicon debris from the lead frame.

FIG. 7 is a top view of the example semiconductor package of FIG. 6 illustrating the spatial relationship between a semiconductor die, leads, and bumps on the leads.

FIG. 8 illustrates an example semiconductor package having a bumped lead frame with etched grooves in lead frame leads to provide isolation.

FIG. 9 illustrates an example method of manufacturing a semiconductor device that provides lead frame isolation from silicon debris.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In the drawings, like reference numerals refer to like elements throughout, and the various features are not necessarily drawn to scale. Corresponding numerals and symbols in the different figures generally refer to corresponding parts, unless otherwise indicated. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor die can include passive devices such as resistors, inductors, filters, or active devices such as transistors. The semiconductor die can be an integrated circuit with hundreds or thousands of transistors coupled to form a functional circuit, for example a microprocessor or memory device.

Semiconductor dies are manufactured from semiconductor wafers. When processing is finished and the semiconductor devices are complete, the semiconductor wafer is separated into individual semiconductor dies by severing the semiconductor wafer along scribe lanes. The separated dies can then be removed and handled individually for further processing including packaging. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

In an example process for singulating semiconductor dies, a wafer sawing method is used. A dicing saw is used to form partial cuts through the semiconductor wafer to form stress induced dislocations along the scribe lanes. In an example arrangement, the partial cut is at least halfway through the semiconductor wafer. In additional examples, the cut can extend from about 70% and up to 99% of the wafer. In an alternative to a mechanical sawing, a laser stealth dicing can be used to create cracks within the wafer without modifying the surface characteristics of a wafer. Dicing tape is applied to the semiconductor wafer prior to cutting, and the dicing tape is stretched after laser stealth dicing. The force applied by the stretching dicing tape causes the cracks in the semiconductor wafer to propagate completely through the semiconductor substrate. As the dicing tape is further stretched, the semiconductor dies are separated from one another as gaps open between semiconductor dies. Singulated semiconductor dies are removed from the dicing tape for packaging. Use of mechanical sawing can cause defects in the singulated dies including loss of dies and chipping and damage to the side surfaces and back surfaces of the singulated dies. The silicon chipping or debris is difficult to be completely eliminated during manufacture, even using a laser stealth dicing process.

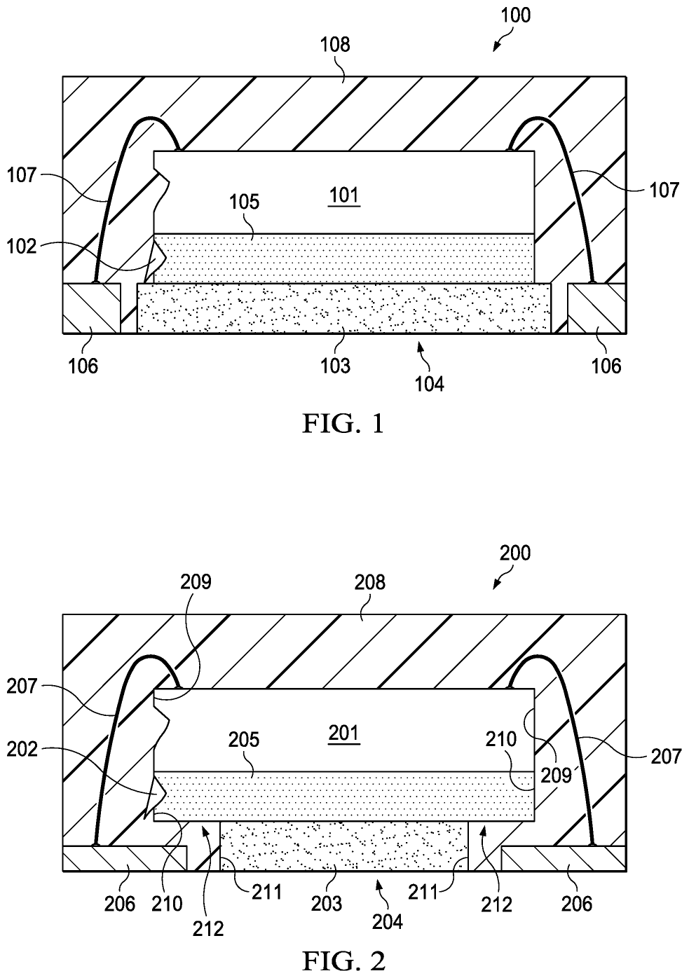

FIG. 1 illustrates a semiconductor package 100 comprising a semiconductor die 101 that has been singulated from a semiconductor wafer using a saw dicing process. During the wafer dicing process, the saw blade creates silicon chipping, such as silicon debris 102. Semiconductor die 101 is attached to a die attach pad 103 of a lead frame 104. For electronic isolation, a non-conductive mount compound or B-stage film 105 is used as a die attach adhesive layer between semiconductor die 101 and lead frame 104. Contacts on semiconductor die 101 are connected to lead terminals 106 on lead frame 104 using bond wires 107. The semiconductor die 101, lead frame 103, adhesive layer 105, and bond wires 107 are encapsulated in mold compound 108 to form package 100.

In some examples, the adhesive layer 105 between semiconductor die 101 and lead frame 104 may be a B-stage material or die attach film that was coated onto the semiconductor wafer backside before the wafer saw process. In other examples, the adhesive layer 105 may be a non-conductive dispensed epoxy that was dispensed onto the lead frame 104 prior to die attaching. Silicon debris 102 may be embedded into the non-conductive adhesive layer 105 during the semiconductor die attach process. The presence of silicon debris 102 can touch the die attach pad 103 and thus result in electrical leakage between semiconductor die 101 and lead frame 104. This type of electronic leakage is a general problem for electrically isolated devices in the semiconductor industry since the silicon chipping or debris may be embed into non-conductive material layers and induce electronic leakage. It will be understood that the components of semiconductor package 100, such as silicon debris 102, are not shown to scale in FIG. 1 and that the relative sizes of the components are exaggerated in the figures herein for purposes of illustration.

The example semiconductor packages disclosed herein describe lead frame configurations that provide solutions to avoid leakage risk for an electrically isolated device. The lead frame in a semiconductor package may be designed with a bumped structure or a non-coplanar structure. The bumped area or a selective area of the lead frame that is higher than other areas of the lead frame support a central area of the semiconductor die, which allows the semiconductor die edge to overhang the lead frame. The overhang structure ensures that the die edge does not connect with the lead frame 104 physically and thereby avoids the leakage problem.

FIG. 2 illustrates an example semiconductor package 200 comprising a semiconductor die 201 and silicon debris 202 that has been created during a semiconductor wafer singulation process. Semiconductor die 201 is attached to a die attach pad 203 of a lead frame 204. Non-conductive mount compound or B-stage film 205 is used as a die attach adhesive layer between semiconductor die 201 and lead frame 204. Contacts on semiconductor die 201 are connected to leads 206 on lead frame 204 using bond wires 207. The semiconductor die 201, lead frame 203, adhesive layer 205, and bond wires 207 are encapsulated in mold compound 208 to form package 200.

The width of die attach pad 203 is smaller than the widths of semiconductor die 201 and adhesive layer 205. The sidewalls 209 of semiconductor die 201 and sidewalls 210 of adhesive layer 205 extend beyond the sidewalls 211 of die attach pad 203. This creates a region 212 where semiconductor die 201 and adhesive layer 205 overhang but do not contact the die attach pad 203 portion of lead frame 204. Additionally, leads 206 are half etched and extend beneath the sidewalls 209 of semiconductor die 201 and sidewalls 210 of adhesive layer 205 and into the overhanging region 212. The overhanging region 212 creates a space that is filled by mold compound 208, which is an electrical isolation material. Silicon debris 202 is physically separated from the die attach pad 203 and lead terminal 206 portions of lead frame 204, which prevents silicon debris 202 from creating an electrical leakage between semiconductor die 201 and lead frame 204. As used herein, “overhang” or “overhanging” means that edges of the semiconductor die 201 and the adhesive layer 205 extend beyond the edges of the die attach pad 203 so that the edges of the semiconductor die 201 and the adhesive layer 205 are not adjacent to, and do not touch, the die attach pad or any other portion of the lead frame.

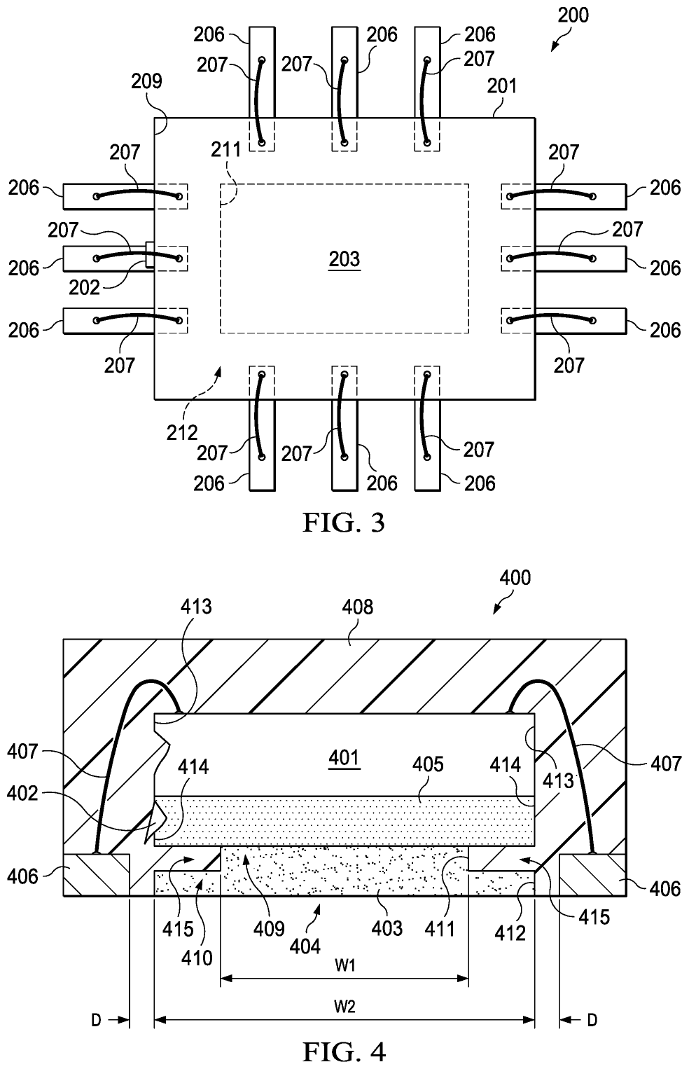

FIG. 3 is a top view of the example semiconductor package 200 of FIG. 2 illustrating the spatial relationship between semiconductor die 201, die attach pad 203, and lead frame leads 206. Mold compound 208 is not shown in FIG. 3 to simplify the drawing. The overhanging region 212 provides separation between the sidewalls 209 of semiconductor die 201 and the sidewalls 211 of die attach pad 203 so that silicon debris 202 does not create an electrical short to lead frame leads 206 or die attach pad 203.

FIG. 4 illustrates example semiconductor package 400 having another lead frame configuration. Semiconductor package 400 comprises a semiconductor die 401 and silicon debris 402, which was created during a semiconductor wafer singulation process for example. Semiconductor die 401 is attached to a die attach pad 403 of a lead frame 404. Non-conductive mount compound or B-stage film 405 is used as a die attach adhesive layer between semiconductor die 401 and lead frame 404. Contacts on semiconductor die 401 are connected to leads 406 on lead frame 404 using bond wires 407. The semiconductor die 401, lead frame 403, adhesive layer 405, and bond wires 407 are encapsulated in mold compound 408 to form package 400.

Die attach pad 403 has an upper portion 409 and a lower portion 410. The upper portion 409 of die attach pad 403 is smaller than lower portion 410, such as by having a smaller width W1 on the upper portion 409 compared to the width W2 of lower portion 410. In one example, upper portion 409 has been etched, such as half-etched, so that the sidewalls 411 of the upper portion 409 are recessed inward of sidewalls 412 on the lower portion 410. The sidewalls 413 of semiconductor die 401 and sidewalls 414 of adhesive layer 405 extend beyond the sidewalls 411 of upper portion 409 on die attach pad 403. This creates a region 412 where semiconductor die 401 and adhesive layer 405 overhang but do not contact the die attach pad 403 portion of lead frame 404. Leads 406 are separated horizontally from semiconductor die 401, adhesive layer 405, and/or die attach pad 403 by a distance D. The overhanging region 415 and the space between the leads 406 and die attach pad 403 are filled by mold compound 408.

Silicon debris 402 is physically separated from the die attach pad 403 and lead terminal 406 portions of lead frame 404 by the overhang region 415 and the horizontal separation D. This prevents silicon debris 402 from creating an electrical leakage between semiconductor die 401 and lead frame 404.

In some examples, the sidewalls 412, 413, and 414 do not need to be aligned horizontally. Instead, the outer width W2 of die attach pad 403 may be greater or less than the width of adhesive layer 405. As long as the sidewall 411 of upper die attach pad portion 403 is inward of the sidewall 414 of adhesive layer 405, then the recessed area 415 will provide isolation between silicon debris 402 in the adhesive layer 405 and the die attach pad 403.

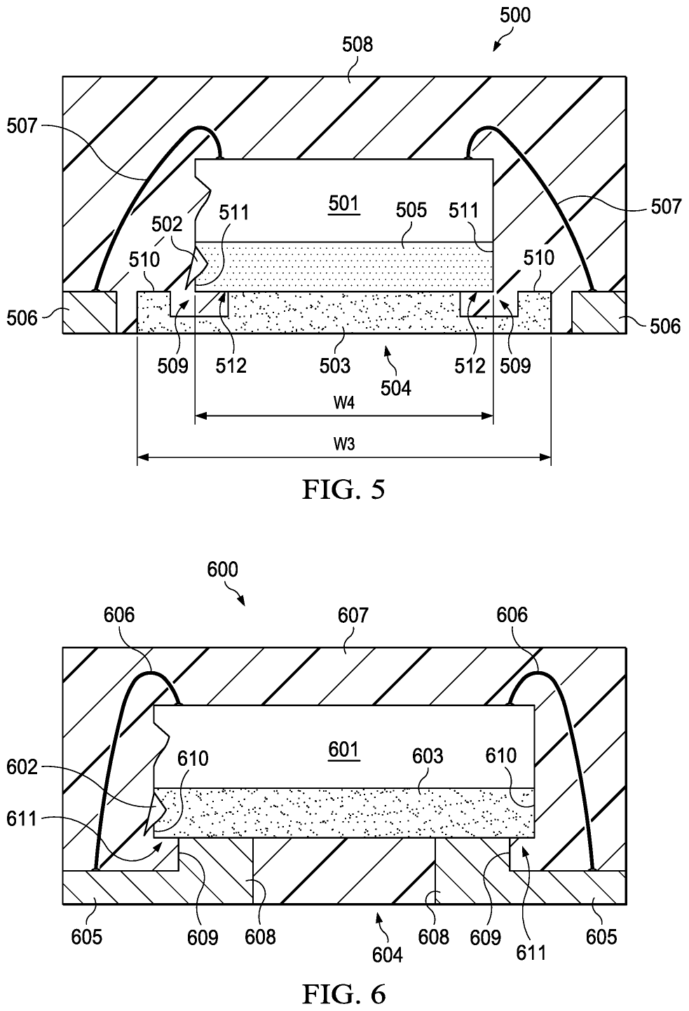

FIG. 5 illustrates example semiconductor package 500 having another variation of a lead frame configuration. Semiconductor package 500 comprises a semiconductor die 501 and silicon debris 502, which was created during a semiconductor wafer singulation process for example. Semiconductor die 501 is attached to a die attach pad 503 of a lead frame 504. Non-conductive mount compound or B-stage film 505 is used as a die attach adhesive layer between semiconductor die 501 and lead frame 504. Contacts on semiconductor die 501 are connected to leads 506 on lead frame 504 using bond wires 507. The semiconductor die 501, lead frame 503, adhesive layer 505, and bond wires 507 are encapsulated in mold compound 508 to form package 500.

In semiconductor package 500, die attach pad 503 has a width W3 that is greater than the width W4 of adhesive layer 505. Grooves 509 are etched into the top surface 510 of die attach pad 503. In one example, the grooves 509 are half-etched into die attach pad 503. The grooves 509 are etched into the upper surface 510 of lead frame 504 prior to placement of the adhesive layer 505 and semiconductor die 501 on die attach pad 503. The grooves 509 are generally centered around the sidewalls 511 of adhesive layer 505. The grooves 509 are filled by mold compound 508. Grooves 509 create a region 512 where semiconductor die 501 and adhesive layer 505 overhang but do not contact the die attach pad 503 portion of lead frame 504. Leads 506 are separated horizontally from semiconductor die 501, adhesive layer 505, and/or die attach pad 503. Silicon debris 502 is physically separated from the die attach pad 503 portion of lead frame 504 by the grooves 509. The grooves 509 prevent silicon debris 502 from creating an electrical leakage between semiconductor die 501 and lead frame 504.

FIG. 6 illustrates example semiconductor package 600 having a bumped structure on a lead frame. Semiconductor package 600 comprises a semiconductor die 601 and silicon debris 602, which was created during a semiconductor wafer singulation process, for example. A non-conductive mount compound or B-stage film 603 is used as a die attach adhesive layer between semiconductor die 601 and a lead frame 604. The lead frame 604 comprises a plurality of leads 605. Contacts on semiconductor die 601 are connected to leads 605 on lead frame 604 using bond wires 606. The semiconductor die 601, adhesive layer 603, lead frame 604, and bond wires 606 are encapsulated in mold compound 607 to form package 600.

A bump structure 608 is formed on each lead 605. The bump structure 608 may be the same material as lead 605, such as copper. Semiconductor die 601 is attached to bumps 608 by adhesive layer 603. The bumps 608 and leads 605 are configured so that an outer sidewall 609 of bumps 608 is positioned inward of the sidewall 610 of adhesive layer 603. This configuration creates a region 611 where adhesive layer overhangs but does not contact leads 605. The overhanging region 611 physically separates silicon debris 602 from the bump 608 and lead 605. This separation prevents silicon debris 602 from creating an electrical leakage between semiconductor die 601 and lead frame 604.

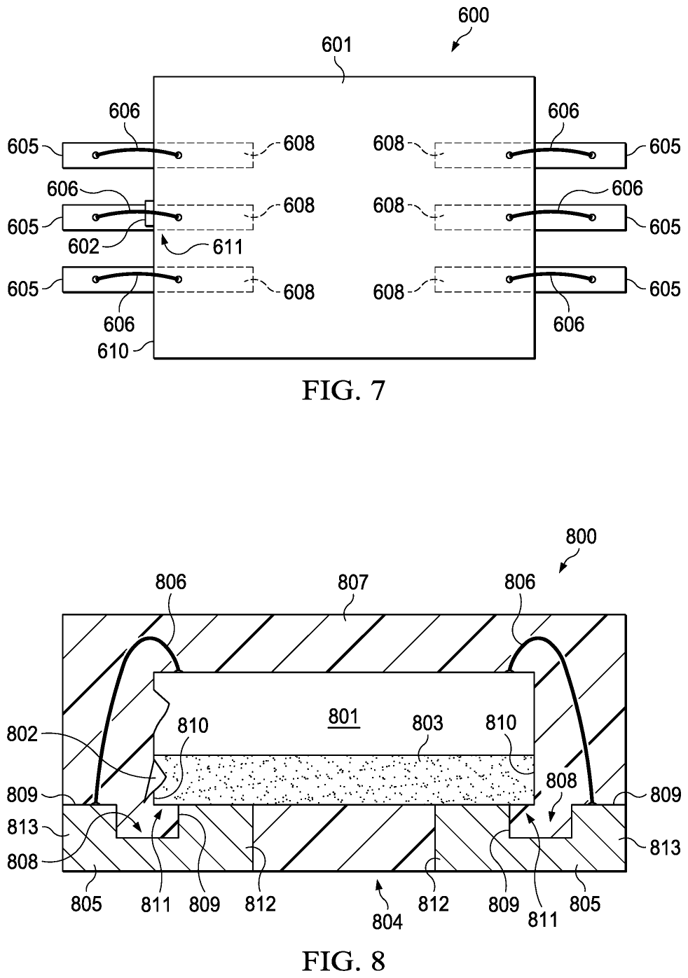

FIG. 7 is a top view of the example semiconductor package 600 of FIG. 6 illustrating the spatial relationship between semiconductor die 601, leads 605, and bumps 608. Mold compound 607 is not shown in FIG. 7 to simplify the drawing. The overhanging region 611 provides separation between the sidewall 610 of adhesive layer 603 and the bumps 608 so that silicon debris 602 does not create an electrical short to lead frame leads 605.

FIG. 8 illustrates an example semiconductor package 800 having a lead frame with an etched groove to provide isolation. Semiconductor package 800 comprises a semiconductor die 801 and silicon debris 802, which was created during a semiconductor wafer singulation process, for example. A non-conductive mount compound or B-stage film 803 is used as a die attach adhesive layer between semiconductor die 801 and a lead frame 804. The lead frame 804 comprises a plurality of leads 805. Contacts on semiconductor die 801 are connected to leads 805 on lead frame 804 using bond wires 806. The semiconductor die 801, adhesive layer 803, lead frame 804, and bond wires 806 are encapsulated in mold compound 807 to form package 800.

A groove 808 is etched into the top surface 809 of each lead 805. In one example, the grooves 808 are half-etched into leads 805. The grooves 808 are etched into the upper surface 809 of leads 808 prior to placement of the adhesive layer 803 and semiconductor die 801 on leads 805. The grooves 808 are generally centered around the sidewalls 810 of adhesive layer 803. The grooves 808 are filled by mold compound 807. Grooves 808 create a region 811 where semiconductor die 801 and adhesive layer 803 overhang but do not contact the leads 805 portion of lead frame 804. Silicon debris 802 is physically separated from the leads 805 by the grooves 808. The grooves 808 prevent silicon debris 802 from creating an electrical leakage between semiconductor die 801 and lead frame 804.

In another example, instead of etching the groove 808 into leads 805, an inner bump portion 812 and an outer bump portion 813 may be added to leads to create the groove 808.

The non-coplanar lead frames and bumped lead frames as illustrated in the example semiconductor packages may be manufactured, for example, by a lead frame supplier or may be created during manufacture of the semiconductor packages.

The silicon debris, chipping, or splinters always occur at the edge area of the semiconductor die. With the packaging concepts shown in the examples herein, the die edge is placed in an overhanging configuration without contacting the lead frame and, as a result, leakage caused by silicon debris is avoided.

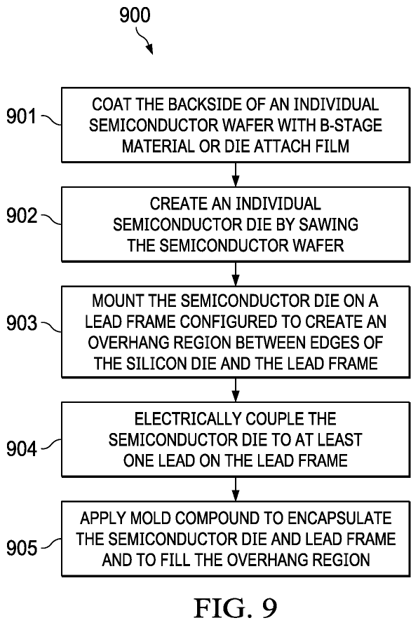

FIG. 9 illustrates an example method 900 of manufacturing a semiconductor device that provides lead frame isolation from silicon debris. In step 901, an individual wafer is coated with B-stage material or die attach film on its backside. In step 902, an individual semiconductor die with B-stage material or die attach film is created by sawing the semiconductor wafer with B-stage material or die attach film on its backside. As discussed herein, silicon debris may be created during the saw singulation of the semiconductor wafer.

In step 902, the semiconductor die is mounted on a lead frame. The lead frame is configured to create an overhanging region between the edges of the semiconductor die and the lead frame. The semiconductor die may be attached to the lead frame using a non-conductive mount compound or B-stage film and does not require an additional metal coating on the backside of the semiconductor die. In one example, the overhang region may be created, for example, by using a lead frame with a die attach pad that is smaller than the semiconductor die as described in connection with semiconductor packages 200, 400, and 500 shown in FIGS. 2, 4, and 5. In another example, the overhang region may be created, for example, by using a groove etched into the lead frame as described in connection with semiconductor packages 500 and 800 as shown in FIGS. 5 and 8. In a further example, the overhang region may be created, for example, by using bumped structures on the lead frame as described in connection with semiconductor packages 600 and 800 as shown in FIGS. 6 and 8.

In step 903, the semiconductor die is electrically coupled to at least one lead on the lead frame. In one example, contacts on the semiconductor die are electrically coupled to leads using a bond wire.

In step 904, after the semiconductor die has been mounted on the lead frame, apply a non-conductive mold compound to the semiconductor die and the lead frame to fill the overhang region and to encapsulate the semiconductor die and the lead frame.

An example integrated circuit package includes a silicon die having a first side and a second side, an adhesive layer attached to the first side of the silicon die, a die attach pad having a mounting surface, and one or more leads that are spaced apart from the edges of the silicon die and the adhesive layer. The mounting surface has a smaller area than an area of the adhesive layer. The silicon die is mounted on the lead frame at the mounting surface so that edges of the silicon die and the adhesive layer overhang the die attach pad without touching the die attach pad. The silicon die has a first width and a first length. The die attach pad has a second width that is less than the first width and a second length that is less than the first length. The edges of the silicon die and the adhesive layer overhang all edges of the die attach pad.

The die attach pad may have a top portion and a bottom portion, wherein the die attach pad has an etched area so that the top portion has a smaller length and width than the bottom portion. The etched area in the top portion of the die attach pad may be half-etched.

The die attach pad may have a top surface. A groove may be etched in the top surface surrounding the mounting surface. The silicon die may be mounted on the mounting surface so that the edges of the silicon die and the adhesive layer overhang the groove.

The edges of the silicon die and the adhesive layer may overhang the one or more leads. The one or more leads may be etched to have a thickness that is less than a thickness of the die attach pad.

The one or more leads may be laterally spaced apart from the edges of the silicon die and the adhesive layer.

The example integrated circuit package may further include one or more bond wires coupling contacts on the second side of the silicon die to the one or more leads, a silicon chip attached to an edge of the adhesive layer, and a mold compound encapsulating the semiconductor die, the adhesive layer, and the die attach pad, the mold compound filling a space where the edges of the silicon die and the adhesive layer overhang the die attach pad.

Another example semiconductor device includes a silicon die having a first side and a second side, an adhesive layer attached to the first side of the silicon die, and a plurality of leads. The leads have a first end, a second end, and a central portion between the first end and the second end. A bump is formed on each of the first ends of the leads. The silicon die is mounted on the bumps so that edges of the silicon die and the adhesive layer overhang the central portion of the leads without touching the central portion of the leads and the second ends of the leads extend beyond the edges of the silicon die and the adhesive layer.

The bumps may be formed by adding material to the first ends of the leads.

The bumps may be formed by etching the leads so that the central portion and the second end are thinner than the first end.

The bumps may be formed by etching the central portion of the leads so that the central portion is thinner than the first end and the and the second end. The etched central portion may form a groove, and the edges of the silicon die and the adhesive layer overhang the groove.

The example semiconductor device may further include one or more bond wires coupling contacts on the second side of the silicon die to the second end of the leads, a silicon chip attached to an edge of the adhesive layer, and a mold compound encapsulating the semiconductor die, the adhesive layer, and at least a portion of the leads, the mold compound filling a space where the edges of the silicon die and the adhesive layer overhang the central portion of the leads.

An example method of making a semiconductor device includes the steps of providing a silicon wafer having a backside, coating the wafer backside with an adhesive layer, sawing the silicon wafer to create a semiconductor die, and providing a lead frame comprising a die attach pad having a mounting surface, the mounting surface having a smaller area than an area of the adhesive layer, and one or more leads. The example method of making a semiconductor device further includes the steps of mounting the silicon die on the lead frame at the mounting surface so that edges of the silicon die and the adhesive layer overhang the die attach pad without touching the die attach pad, and encapsulating the semiconductor die, the adhesive layer, and the lead frame with a mold compound so that the mold compound fills a space where the edges of the silicon die and the adhesive layer overhang the die attach pad.

The example method of making a semiconductor device may further include mounting the silicon die so that the one or more leads are spaced apart from the edges of the silicon die and the adhesive layer.

The example method of making a semiconductor device further include etching the die attach pad to create a space where the edges of the silicon die and the adhesive layer overhang the die attach pad.

The example method of making a semiconductor device further include etching the one or more leads to create a space where the edges of the silicon die and the adhesive layer overhang the one or more leads.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A integrated circuit (IC) package, comprising:
a silicon die having a first side and a second side;
an adhesive layer attached to the first side of the silicon die;
a die attach pad having a mounting surface, the mounting surface having a smaller area than an area of the adhesive layer, the silicon die mounted on the lead frame at the mounting surface so that edges of the silicon die and the adhesive layer overhang the die attach pad without touching the die attach pad; and
one or more leads that are spaced apart from the edges of the silicon die and the adhesive layer.

2. The IC package of claim 1, wherein the silicon die has a first width and a first length, the die attach pad has a second width that is less than the first width and a second length that is less than the first length, and the edges of the silicon die and the adhesive layer overhang all edges of the die attach pad.

3. The IC package of claim 1, wherein the die attach pad has a top portion and a bottom portion, the die attach pad having an etched area so that the top portion has a smaller length and width than the bottom portion.

4. The IC package of claim 3, wherein the etched area in the top portion of the die attach pad is half-etched.

5. The IC package of claim 1, wherein the die attach pad has a top surface, and a groove is etched in the top surface surrounding the mounting surface.

6. The IC package of claim 5, wherein the silicon die is mounted on the mounting surface so that the edges of the silicon die and the adhesive layer overhang the groove.

7. The IC package of claim 1, wherein the edges of the silicon die and the adhesive layer overhang the one or more leads.

8. The IC package of claim 7, wherein the one or more leads are etched to have a thickness that is less than a thickness of the die attach pad.

9. The IC package of claim 1, wherein the one or more leads are laterally spaced apart from the edges of the silicon die and the adhesive layer.

10. The IC package of claim 1, further comprising:
one or more bond wires coupling contacts on the second side of the silicon die to the one or more leads;
a silicon chip attached to an edge of the adhesive layer; and
a mold compound encapsulating the semiconductor die, the adhesive layer, and the die attach pad, the mold compound filling a space where the edges of the silicon die and the adhesive layer overhang the die attach pad.

11. A semiconductor device, comprising:
a silicon die having a first side and a second side;
an adhesive layer attached to the first side of the silicon die;
a plurality of leads, the leads having a first end, a second end, and a central portion between the first end and the second end;
a bump formed on each of the first ends of the leads; and
the silicon die mounted on the bumps so that edges of the silicon die and the adhesive layer overhang the central portion of the leads without touching the central portion of the leads and the second ends of the leads extend beyond the edges of the silicon die and the adhesive layer.

12. The semiconductor device of claim 11, wherein the bumps are formed by adding material to the first ends of the leads.

13. The semiconductor device of claim 11, wherein the bumps are formed by etching the leads so that the central portion and the second end are thinner than the first end.

14. The semiconductor device of claim 11, wherein the bumps formed by etching the central portion of the leads so that the central portion is thinner than the first end and the and the second end.

15. The semiconductor device of claim 14, wherein the etched central portion forms a groove, and wherein the edges of the silicon die and the adhesive layer overhang the groove.

16. The semiconductor device of claim 11, further comprising:
one or more bond wires coupling contacts on the second side of the silicon die to the second end of the leads;
a silicon chip attached to an edge of the adhesive layer; and
a mold compound encapsulating the semiconductor die, the adhesive layer, and at least a portion of the leads, the mold compound filling a space where the edges of the silicon die and the adhesive layer overhang the central portion of the leads.

17. A method of making a semiconductor device, comprising:
providing a silicon wafer having a backside;
coating the wafer backside with an adhesive layer;
sawing the silicon wafer to create a semiconductor die;
providing a lead frame comprising:
a die attach pad having a mounting surface, the mounting surface having a smaller area than an area of the adhesive layer; and
one or more leads;
mounting the silicon die on the lead frame at the mounting surface so that edges of the silicon die and the adhesive layer overhang the die attach pad without touching the die attach pad; and
encapsulating the semiconductor die, the adhesive layer, and the lead frame with a mold compound so that the mold compound fills a space where the edges of the silicon die and the adhesive layer overhang the die attach pad.

18. The method of claim 17, further comprising:
mounting the silicon die so that the one or more leads are spaced apart from the edges of the silicon die and the adhesive layer.

19. The method of claim 17, further comprising:
etching the die attach pad to create a space where the edges of the silicon die and the adhesive layer overhang the die attach pad.

20. The method of claim 17, further comprising:
etching the one or more leads to create a space where the edges of the silicon die and the adhesive layer overhang the one or more leads.
